(19) United States
(12) Patent Application Publication
(10) Pub. No.: US 2016/0035933 A1
(43) Pub. Date: Feb. 4, 2016

(54) THICK WINDOW LAYER LED MANUFACTURE

(71) Applicant: EPISTAR CORPORATION, Hsinchu (TW)

(72) Inventors: Yea-Chen LEE, Zhubei City (TW); Jung-Tang CHU, Zhunan Township (TW); Ching-Hua CHIU, Hsinchu City (TW); Hung-Wen HUANG, Hsinchu City (TW)

(21) Appl. No.: 14/883,265

(22) Filed: Oct. 14, 2015

Related U.S. Application Data
(62) Division of application No. 13/276,108, filed on Oct. 18, 2011.

(51) Int. Cl. H01L 33/00

(52) U.S. Cl. CPC H01L 33/0095; H01L 2933/0016; H01L 2933/0033

(57) ABSTRACT

A LED die and method for bonding, dicing, and forming the LED die are disclosed. In an example, the method includes forming a LED wafer, wherein the LED wafer includes a substrate and a plurality of epitaxial layers disposed over the substrate, wherein the plurality of epitaxial layers are configured to form a LED; bonding the LED wafer to a base-board to form a LED pair; and after bonding, dicing the LED pair, wherein the dicing includes simultaneously dicing the LED wafer and the base-board, thereby forming LED dies.

### TECHNICAL FIELD

The present disclosure relates to light emitting diode devices and methods for manufacturing light emitting diode devices.

### BACKGROUND

Light emitting diodes (LEDs) have experienced rapid growth. LEDs have been referred to as a new generation light source, one capable of replacing incandescence lamps, fluorescent lamps and high-intensity discharge lamps. When compared to incandescence light sources, LEDs not only significantly reduce power consumption, but also exhibit longer lifetime, faster response speed, more compact size, lower maintenance costs, and greater reliability. LEDs have thus found many applications, including backlighting for displays, automotive lighting, general lighting, and flash for mobile camera or compact.

Conventional LED device manufacturing includes forming a stack of active layers (such as compound semiconductors including GaN, AlGaN, and InGaN and/or a quantum well stack, such as a single quantum well (SQW) or multiple quantum well (MQW)) over a substrate (such as a sapphire or silicon carbide substrate) to form an LED wafer; forming electrical connections and isolation; dicing the LED wafer to form individual LED dies; bonding each of the LED dies to a base-board; and dicing the base-board to provide the individual LED dies bonded to a base-board. The base-board can provide at least three functions: heat clearance for the LED die; electrical connections for the LED die; and physical support for the LED die. During LED manufacturing, challenges arise in the singulation processes, where the LED wafer is diced into individual the individual LED dies. For example, conventional singulation methods, such as mechanical singulation by diamond scribing and blade dicing or laser scribing and breaking, require that the substrate of the LED wafer (such as the sapphire or silicon carbide substrate) be thinned before dicing. Such thinning can decrease light extraction efficiency of the LEDs. Accordingly, although existing approaches have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for bonding and dicing a LED wafer according to aspects of the present disclosure.

FIGS. 2-5 illustrate diagrammatic cross-sectional views of an embodiment of a LED wafer during various fabrication stages according to the method of FIG. 1.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

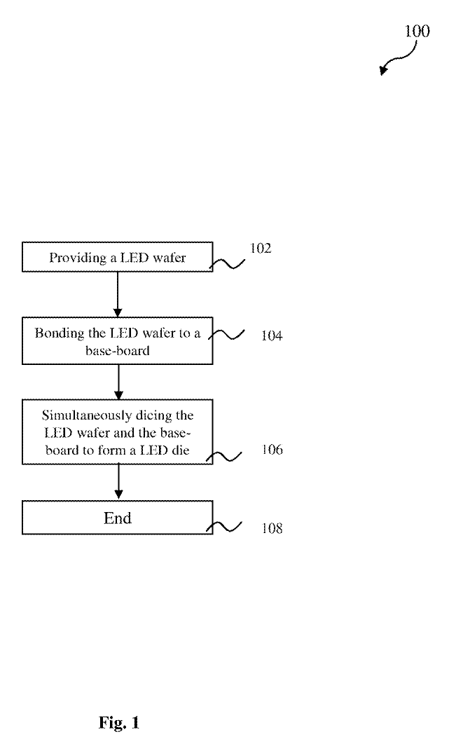

FIG. 1 is a flow chart of a method 100 of bonding and dicing a light emitting diode (LED) wafer, according to various aspects of the present disclosure. The method 100 begins at block 102 where a LED wafer is provided. The LED wafer may include a stack of optical active layers grown over a substrate, electrical connection features and isolation features. The LED wafer is ready for bonding and dicing processes. At block 104, the LED wafer is bonded to a base-board to form a LED pair (LED wafer/base-board). A flip-chip process may apply before bonding process and a thermal process may apply after bonding process. At block 106, the LED wafer and the base-board is diced simultaneously to form a LED device. In an example, two separate dicing systems are used in the dicing process, one for dicing the LED wafer and another one for dicing the base-board. The two dicing systems are aligned to each other and then, the simultaneously dicing can be implemented. At block 108, the bonding and dicing processes are completed. Additional steps can be provided before, during, and after the method 100, and some of the steps described can be replaced or eliminated for additional embodiments of the method. The discussion that follows illustrates various embodiments of a LED device that can be fabricated according to the method 100 of FIG. 1.

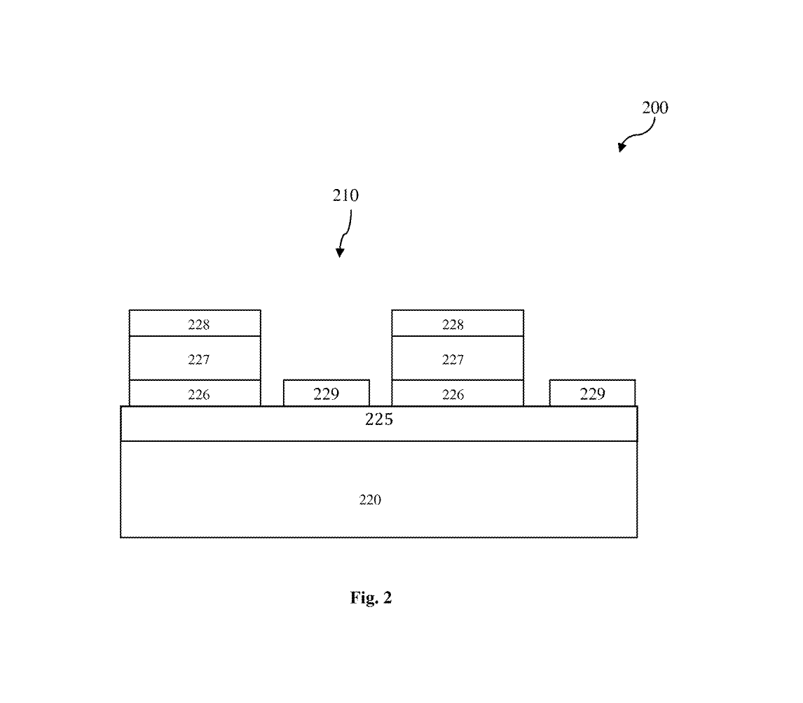

FIGS. 2-5 are various diagrammatic cross-sectional views of an embodiment of a LED device 200 during various fabrication stages according to the method 100 of FIG. 1. FIGS. 2-5 have been simplified for the sake of clarity to better understand the inventive concepts of the present disclosure. In the depicted embodiment, as will be further discussed below, the LED device 200 includes a substrate, a stack of optical active layers, electrical connection features, isolation features, and a base-board. Additional features can be added in the LED device 200 and some of the features described below can be replaced or eliminated for additional embodiments of the LED device 200.

In FIG. 2, the LED device 200 includes a LED wafer 210. The LED wafer 210 includes a substrate 220. When considering a substrate, several characteristics of the substrate are considered, such as conductivity, lattice mismatching level, thermal conductivity, light transparency, and cost. In the depicted embodiment, the substrate 220 includes sapphire. Alternatively, the substrate 220 may include silicon carbide, silicon, GaN, other suitable materials, or combination thereof.

The LED wafer 210 includes material layers disposed over the substrate 220. For example, various epitaxy layers 225, 226, and 227 are formed over the substrate 220. The epitaxy layers 225,226, and 227 are designed to form one of more LEDs. In an example, the epitaxy layers include an n-type doped semiconductor layer and a p-type doped semiconductor layer configured to emit spontaneous radiation. In an example, the epitaxy layers include a single quantum well (SQW) structure disposed between the n-type doped semiconductor layer and the p-type doped semiconductor layer. The SQW structure includes two different semiconductor materials and can be used to tune the wavelength of the LED. Alternatively, a multiple quantum well (MQW) structure is interposed between the n-type doped semiconductor layer and p-type doped semiconductor layer. The MQW structure includes a plurality of SQWs in a stack. The MQW structure preserves advantages of the SQW structure and has a larger volume of active region, allowing higher lighting power. In the depicted embodiment, the epitaxy layers 225, 226, and 227 include GaN based semiconductor materials configured to form GaN-based LEDs that emit blue light, ultraviolet (UV) light, or both. For example, the epitaxy layer 225 is an n-type doped GaN layer (n-GaN layer) disposed over the substrate 220, the epitaxy layer 226 is a MQW structure disposed over the n-GaN layer, and the epitaxy layer 227 is a p-type doped GaN (p-GaN) layer disposed over the MQW structure.

The epitaxy layer 225 (n-GaN layer) is epitaxially grown over the substrate 220. The n-GaN layer includes a gallium nitride layer doped with an n-type dopant, such as silicon or oxygen. In an example, a buffer layer, such as an undoped GaN layer or an aluminum nitride (AlN) layer, may be disposed between the epitaxy layer 225 (n-GaN layer) and the substrate 220. The buffer layer may be epitaxially grown over the substrate 220 before the n-GaN layer 225.

The epitaxy layer 226 (MQW structure) is formed over the epitaxy layer 225 (n-GaN layer) by various eqitaxially growth processes. The MQW structure includes a plurality of pairs of semiconductor films, such as from about 5 pairs to about 15 pairs of semiconductor films. In an example, each pair of semiconductor films includes an indium gallium nitride (InGaN) film and a gallium nitride (GaN) film (forming InGaN/GaN pairs). The InGaN/GaN films can be doped with a n-type dopant. In another example, each pair of semiconductor films includes an aluminium gallium nitride (AlGaN) film and a gallium nitride film (forming AlGaN/GaN pairs). The AlGaN/GaN films can doped with a n-type dopant.

The epitaxy layer 227 (p-GaN layer) is epitaxially grown over the epitaxy layer 226 (MQW structure). The p-GaN layer includes a gallium nitride layer doped with a p-type dopant, such as magnesium, calcium, zinc beryllium, carbon, or combination thereof.

The various epitaxy layers 225, 226, and 227 can be epitaxially grown by a suitable technique, such as metal organic chemical vapor deposition (MOCVD) or metal organic vapor phase epitaxy (MOVPE). In an example, the n-GaN layer (epitaxy layer 225), the MQW structure (epitaxy layer 226), and the p-GaN layer (epitaxy layer 227) can be epitaxially grown using gallium-containing precursor and nitrogen-containing precursor. The gallium-containing precursor includes trimethylgallium (TMG), triethylgallium (TEG), or other suitable chemical. The nitrogen-containing precursor includes ammonia (NH₃), tertiarybutylamine (TBAm), phenylhydrazine, or other suitable chemical. In another example, where the MQW structure (epitaxy layer 226) includes AlGaN films, the AlGaN films can be epitaxy grown by MOVPE using aluminum-containing precursor, gallium-containing precursor, and nitrogen-containing precursor. The aluminum-containing precursor includes TMA, TEA or other suitable chemical; the gallium-containing precursor includes TMG, TEG, or other suitable chemical; and the nitrogen-containing precursor includes ammonia, TBAm, phenyl hydrazine, or other suitable chemical. Alternatively, the various epitaxy layers can be epitaxially grown by another suitable technique, such as hydride vapor phase epitaxy (HVPE) or molecular beam epitaxy (MBE). For example, a GaN layer (such as the buffer layer) can be epitaxially grown by HVPE with source materials including gallium chloride and ammonia gases.

The LED wafer 210 further includes a metal layer 228 and a metal layer 229. The metal layer 228 is disposed over the epitaxy layer 227 (in the depicted embodiment, p-GaN layer) and serves as a contact for electrical connection to the epitaxy layer 227, and the metal layer 229 is disposed over the epitaxy layer 220 (in the depicted embodiment, n-GaN layer) and serves as a contact for electrical connection to the epitaxy layer 225. The metal layers 228 and 229 may include multiple metal layers or films, each serving various functions. The metal layers 228 and 229 include materials such as nickel (Ni), chromium (Cr), aluminum (Al), titanium (Ti), platinum (Pt), palladium (Pd), gold (Au), silver (Ag), indium (In), zinc (Zn), tin (Sn), beryllium (Be), indium tin oxide (ITO), alloys thereof, other suitable materials, or combinations thereof. In an example, the metal layer 228 can include a first metal film disposed on the p-GaN layer, a second metal film disposed on the first metal film, and a third metal film disposed over the second metal film. The first metal film serves as a contact to electrically connect the p-GaN layer, and thus, the first metal film includes a transparent conductive film, such as ITO, formed on the p-GaN layer. In another example, the first metal film includes Ni, Cr, or other suitable metal. The second metal film serves as a reflector disposed on the first metal film. The second metal film (or reflector) has a high reflectivity to light emitted by the LED, thereby increasing light emission efficiency. The second metal film includes Al, Ti, Pt, Pd, Ag, or other suitable metal. The third metal film serves as boding metal designed for wafer bonding. The third metal film includes Au, AuSn, AuIn, or other suitable metal to achieve eutectic bonding or other wafer bonding mechanism. The metal layer 229 may also have multiple metal film layers configured as those described with respect to metal layer 228, and specifically configured to serve as electrical connection to the n-GaN layer. The metal layer 229 may thus be referred to as an n-GaN contact (or n-metal). The various metal films can be formed by physical vapor deposition (PVD) or other suitable technique.

In a conventional LED process flow, before a bonding process, a thickness of the substrate, such as substrate 220, is reduced by a thinning process. For example, in a GaN/sapphire LED process, in order to singulate the LED wafer to form a LED die, the thickness of the sapphire substrate is thinned down to less than 150 μm, usually 100 μm to 130 μm, by a grinding technique. However, a thinner sapphire substrate thickness decreases light extraction efficiency of LED dies. In the depicted embodiment, thinning the substrate 220 of the LED wafer (for example, by grinding) can be eliminated as well as any post grinding cleaning process. The original thickness of the substrate of the LED wafer, usually at about 600 μm, may be kept and thus the light extraction efficiency may be enhanced. For example, the thickness of the sapphire substrate can be about 600 μm. In some embodiments, the thinning process is not eliminated, but rather reduced, for example, the sapphire substrate may be thinned down to about 250 μm or greater, between about 250 μm to about 600 μm. In still other embodiments, the substrate is thinned down about 150 μm to 300 μm. This thicker substrate of the LED wafer may be referred to as a “window layer”. The thicker window layer enhances LED optical performance. The thicker window layer also reduces or eliminates one process step and reduces the likelihood of breakage during the grinding process.

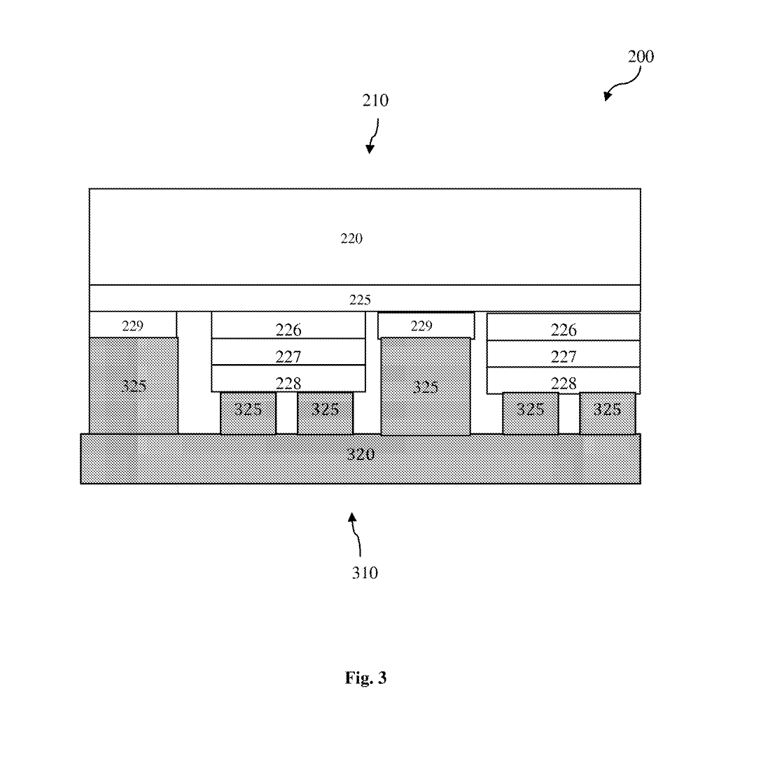

FIG. 3 illustrates the LED wafer 210 bonded to a base-board 310. Various functions may be designed in the base-board 310, such as embedded circuits, electrical and thermal paths, photo detectors, or combination thereof. The base-board 310 includes a substrate 320. The substrate 320 can be Si, Ge, ceramic, SiC, AlN, alloy materials, or a combination of these. In the depicted embodiment, the substrate is a Si sub-mount. A bonding metal 325 is disposed on the substrate 320 that aligns to a surface pattern of the LED wafer 210. The bonding metal 325 includes gold (Au), gold tin (AuSn), gold indium (AuIn), or other suitable metal to achieve eutectic boding or other wafer bonding mechanism. The LED pair (LED wafer 210/base-board 310) may be loaded into a vacuum or ambient chamber and a high temperature and high pressure thermal process may be performed. to achieve bonding. In the thermal process, the LED wafer and base-board bond together chemically.

In the depicted embodiment, during the bonding process, a flip-chip technique is applied. A flip-chip technique is a method to directly connect a face-down (hence, “flipped”) electronic component on to a base-board, by means of conductive bumps that have been deposited onto chip pads on a top side of the wafer and conductive pads that have been deposited onto corresponding locations on the base-board. Flip-chip technique can be used for electronic components such as LEDs, other diodes, transistors, charge-coupled devices (CCD) integrated circuits (IC), passive filters, detector arrays, and microelectromechanical systems (MEMS). In contrast, in a wire bonding technique, electronic components are mounted upright and wires are used to connect the chip pads to external circuitry, such as terminals found in the base-board. There are two ways to perform a flip-chip process: flipping a whole wafer and flipping individual dies. As one example of flipping individual die, a wafer, such as LED wafer 210, is submitted to grinding, lapping, and laser scribing to form LED dies and then each LED die is picked, flipped, and bonded on to a base-board. In contrast, in flipping whole wafer technique, the whole LED wafer is flipped first and bonded to a base-board, and then, the LED pair (LED wafer/base-board) is diced into individual LED dies. Note that the size of the base-boards used in processes of flipping a whole wafer and flipping individual dies is different. The base-boards used in processes where individual dies are flipped are about the size of individual LED dies, while the base-boards used in processes where a whole wafer is flipped are about the size of a whole wafer. The fabrication process of flipping individual die is relatively complicated and throughput is lower compared to flipping a whole wafer process, as described in association with FIG. 3, where a single bonding process is performed to bond the LED wafer 210 to the base-board 310. With whole LED wafer bonding, a method of full surface metal bonding replaces partial metal bump bonding being used in individual die bonding processes. It provides not only a better thermal stability due to larger thermal dispersion path but also a sturdy structure to sustain LED devices

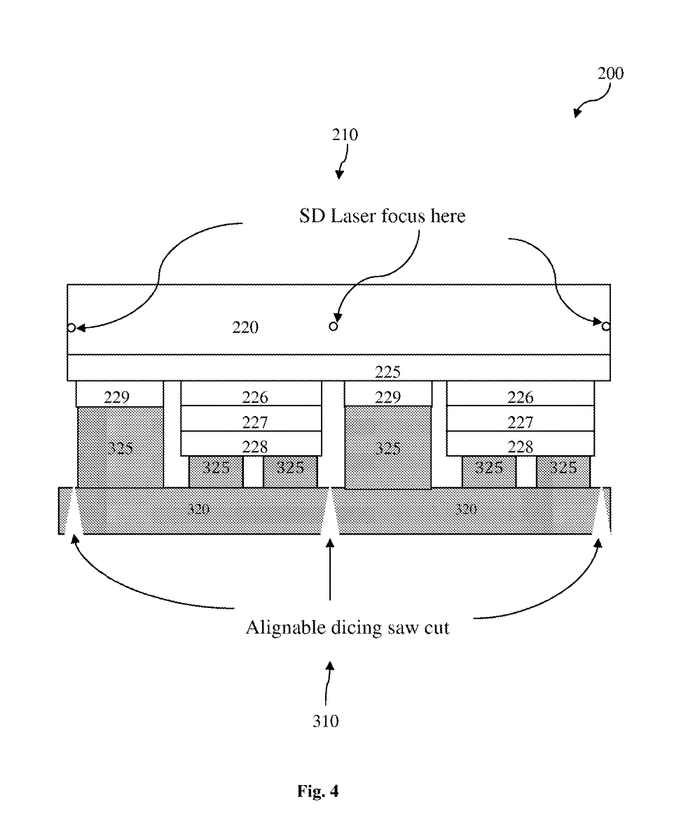

FIG. 4 illustrates dicing the LED pair (LED wafer 210/base-board 310). A top and a bottom dicing system may be aligned to each other, so the LED pair (LED wafer/base-board) can be diced simultaneously from both sides (top and bottom). Typical dicing techniques used in wafer singulation processes include laser scribing and breaking, mechanical scribing and breaking, and diamond blade sawing. In recent years, laser scribing and breaking have become a mainstream method in mass LED manufacturing due to its efficiency. An alternative approach, called Stealth Dicing (SD), is to scribe and break along internal modification regions inside the substrate. One example is dicing the substrate 220 in the LED wafer 210 by SD technology, as shown in FIG. 4. Dicing is accomplished by focusing the output of a picoseond laser inside the substrate 220 (shown as “laser focus” in FIG. 4). This creates cracks within the substrate 220 but does not affect the top and bottom surfaces. Once these cracks are produced, the individual LED dies are broken out from the substrate 220 by using mechanical means, such as a breaker. An example of a breaker is a WBF 4000 LED Breaking machine made by the Opto System Co Ltd. SD can perform multiple modification layers inside substrate (referred to as multi-dicing cycle), which provides a dicing capability for substrates having greater thicknesses. As one example, for dicing a substrate having a thickness more than 150 μm, a multiple modification layers may be performed by using SD technique. Approximately for every 100 μm thickness of a substrate, one modification layer may be needed. An alignment among modification layers (dots of “laser focus”) may be adjusted to form different alignment patterns to achieve a good quality in subsequent process, substrate breaking-off process. As an example, the dots of “laser focus” may be offset from each other. By using SD technology with multiple modification layers capability, the thickness of the substrate 210, such as sapphire, can be kept at above 150 μm and up to 600 μm.

By using SD technology for dicing LED wafer, there are several additional advantages such as no debris is created at the surfaces of the substrate due to an internal modification dicing; a high quality edge is made with minimal residual stress and thermal damage; and a high dicing speed. Both debris-free edges and low thermal damage have been shown to improve extraction efficiency of light from LEDs, providing brighter LED devices. It has been found that edge characteristics of a LED's substrate impacts photon emission from the active multiple quantum well region in the sidewall direction and reflection from metal-coated bottom of the package. Another advantage of debris-free edges is that a post dicing cleaning process can be eliminated.

SD technology is applied on dicing LED wafer by a unit module called “Stealth Dicing Engine” that can be mounted in a wafer dicing system. In the depicted embodiment, the SD engine is mounted to a LED wafer dicing system. A base-board laser scribe system is aligned with the LED wafer dicing system by aligning arrangement equipment. Both sides of the LED pair are then diced simultaneously, shown as “SD laser focus” and “alignable dicing saw cut” in FIG. 4. Alternatively, SD can make a multi-dicing-cycle (multiple dicing runs)on the substrate 220 of the LED wafer 210 first, and then, at the last run or at one of runs, simultaneously dicing the LED wafer 210 and base-board 310. The throughput of dicing process increases greatly by using a simultaneously dicing technique.

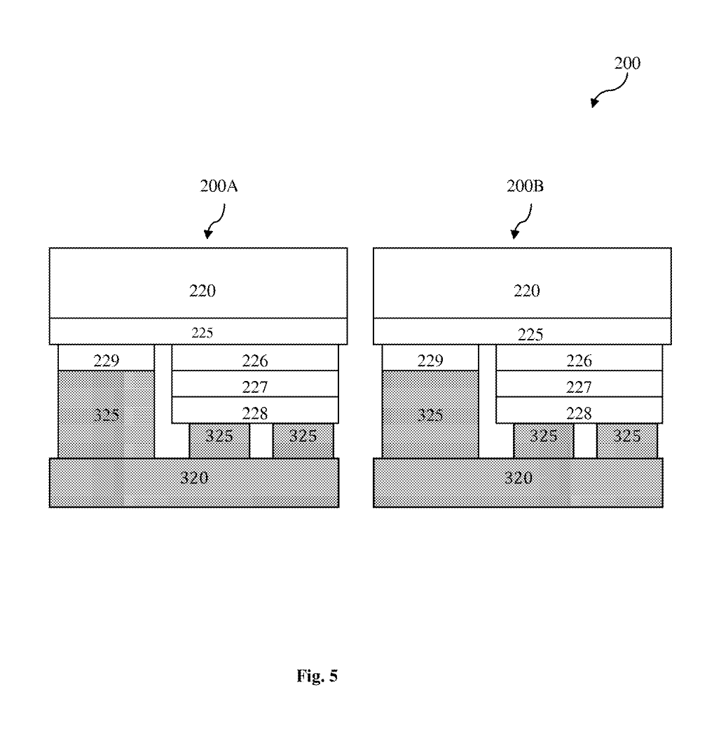

FIG. 5 illustrates individual LED dies, 200A and 200B, formed by breaking the LED pair (after the dicing process) by using a breaker, which breaks the LED pair through “laser focus” points (from top side of the LED pair) and “alignable dicing cuts” (from bottom side of the LED pair) simultaneously. By implementing the process method 100, the LED dies 200A and 200B have a thick window layer; an enhanced light extraction efficiency, a better thermal dispersion by simplified, cleaner and higher throughput processes. Different embodiments may have different advantages, and no particular advantage is necessarily required of any embodiment.

The present disclosure provides for many different embodiments. In an example, a method includes forming a LED wafer; forming a base-board; bonding the LED wafer to the base-board to form a LED pair; and after bonding, dicing the LED pair to form a LED die. The LED wafer includes a substrate and a plurality of epitaxial layers disposed over the substrate. The plurality of epitaxial layers are configured to form a LED. The substrate of the LED wafer includes sapphire. The method may further includes, before the bonding, no thinning process is performed on the substrate of the LED wafer. A thickness of the substrate is greater than or equal to 150 μm. The method may further includes, before the bonding, flipping the LED wafer face down by a flipping process. The method may further includes the base-board includes a Si sub-mount. A bonding metal is disposed over the substrate of the base-board. The bonding includes aligning the bonding metal with a surface pattern of the LED wafer. In an example, the bonding includes a full surface metal bonding. After bonding, a high temperature and high pressure thermal process is performed on the LED pair. The dicing includes simultaneously dicing the LED wafer and the base-board, thereby forming LED dies. In an example, the dicing includes performing multi-dicing cycles on the LED wafer before simultaneously dicing the LED wafer and the base-board. A dicing the LED wafer includes using a Stealth Dicing (SD) technique. A dicing the base-board includes using a laser scribing technique. After dicing, the LED pair is broken into LED dies.

In another example, a method includes forming a LED pair, wherein the LED pair includes a LED wafer bonded with a base-board; dicing the LED pair, wherein the dicing includes simultaneously dicing the LED wafer and the base-board, and further wherein dicing the LED wafer by using a stealth dicing (SD). In an example, using the SD to dice the LED wafer includes dicing a sapphire substrate of the LED wafer, it further comprising performing a multi-dicing cycle on the sapphire substrate and no post dicing cleaning process is performed after using SD technique.

In another example, a method includes forming a LED pair, wherein the LED pair includes a LED wafer bonded with a base-board; aligning a first dicing system with a second dicing system, wherein the first dicing system is configured to dice the LED wafer and the second dicing system is configured to dice the base-board; and after aligning, using the first dicing system and the second dicing system to simultaneously dice the LED pair. In an example, dicing the LED wafer of the LED pair includes using a stealth dicing (SD) technique. and dicing the base-board of the LED pair includes using a laser scribing technique.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and /or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing an LED wafer including a substrate, a first epitaxy layer on the substrate, an active layer on the first epitaxy layer, and a second epitaxy layer on the active layer;
providing a base-board;
bonding the LED wafer to the base-board through a first bonding metal configured to connect to the first epitaxy layer, a second bonding metal configured to connect to the second epitaxy layer, and a third bonding metal which is apart from the second metal and configured to connect to the second epitaxy layer; and
dicing the LED wafer and the base-board substantially at the same time.

2. The method of claim 1, further comprising a step of providing a first metal layer on the first epitaxy layer, and a second metal layer on the second epitaxy layer.

3. The method of claim 2, wherein the first metal layer comprises ITO.

4. The method of claim 2, wherein the first metal is reflective.

5. The method of claim 1, wherein the first epitaxy layer is epitaxially grown on the substrate.

6. The method of claim 1, wherein the first bonding metal, the second bonding metal and the third bonding metal are aligned with a surface pattern of the LED wafer.

7. The method of claim 1, further comprising a step of flipping the LED wafer face down before bonding.

8. The method of claim 1, wherein the dicing step comprises using a Stealth Dicing (SD) technique.

9. The method of claim 1, further comprising separating the first epitaxy layer during dicing the LED wafer.

10. The method of claim 1, wherein the dicing step comprises performing multi-dicing cycles on the LED wafer before dicing the LED wafer and the base-board.
